(19) United States
(12) Patent Application Publication
(10) Pub. No.: US 2015/0194311 A1
(43) Pub. Date: Jul. 9, 2015

(54) Method For Manufacturing Semiconductor Device

(71) Applicant: Macronix International Co., Ltd., Hsinchu (TW)

(72) Inventors: Tao Yuan Lin, Taipei City (TW); I. Chen Yang, Changhua City (TW); Yao Wen Chang, Zhubei City (TW)

(73) Assignee: Macronix International Co., Ltd., Hsinchu (TW)

(21) Appl. No.: 14/150,681

(22) Filed: Jan. 8, 2014

(51) Int. Cl. H01L 21/02; H01L 29/78; H01L 29/66

(52) U.S. Cl. CPC H01L 21/02694; H01L 29/6659; H01L 29/7833; H01L 21/02381; H01L 21/02532

(57) ABSTRACT

A method for forming a semiconductor device includes forming a gate structure over a substrate, performing a lightly-doped drain (LDD) implantation of first dopant ions into the substrate using the gate structure as a mask to form LDD regions in the substrate, performing, after the LDD implantation, a pre-amorphization implantation (PAI) into the substrate using the gate structure as a mask to pre-amorphize at least a portion of the LDD regions, and performing, after the PAI, a high-doping implantation of second dopant ions into the substrate using the gate structure as a mask to form highly-doped regions at least partially overlapping the LDD regions.

### TECHNOLOGY FIELD

The disclosure relates to a method for manufacturing a semiconductor device and, more particularly, to a method for suppressing dopant diffusion during manufacture of a semiconductor device.

### BACKGROUND

During the manufacture of a semiconductor device, impurities may need to be doped into a certain region of a semiconductor layer to change the conductivity of that region. Parameters of such a doped region, for example, a boundary of the doped region, may affect characteristics of the manufactured semiconductor device. However, due to the diffusion of the doped impurities, it may be difficult to control a final doping profile, and thus difficult to control the boundary of the doped region.

For example, when manufacturing a metal-on-semiconductor (MOS) transistor, e.g., a p-type MOS (p-MOS) transistor, on a substrate, e.g., a silicon substrate, impurities need to be doped into the substrate in regions on both sides of a gate structure to form source/drain regions. Profiles of the source/drain regions may affect a current-voltage (I-V) characteristic of the MOS transistor, and thus affect a breakdown voltage of the MOS transistor.

### SUMMARY

In accordance with the disclosure, there is provided a method for forming a semiconductor device. The method includes forming a gate structure over a substrate, performing a lightly-doped drain (LDD) implantation of first dopant ions into the substrate using the gate structure as a mask to form LDD regions in the substrate, performing, after the LDD implantation, a pre-amorphization implantation (PAI) into the substrate using the gate structure as a mask to pre-amorphize at least a portion of the LDD regions, and performing, after the PAI, a high-doping implantation of second dopant ions into the substrate using the gate structure as a mask to form highly-doped regions at least partially overlapping the LDD regions.

Also in accordance with the disclosure, there is provided a semiconductor device. The semiconductor device includes a substrate including a first element, a gate structure formed over the silicon substrate, and a source region and a drain region formed in the silicon substrate at sides of the gate structure. The source and drain regions contain a dopant including a second element different from the first element. The first and second elements are from a same group of the periodic table.

Features and advantages consistent with the disclosure will be set forth in part in the description which follows, and in part will be obvious from the description, or may be learned by practice of the disclosure. Such features and advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1A-1H show a process for forming a semiconductor device according to an exemplary embodiment.

FIG. 2 shows an effect of pre-amorphization on distribution of dopant ions.

FIGS. 3A-3B show two-dimensional dopant distributions in a device manufactured using a conventional method and in a device manufactured using a method according to an exemplary embodiment, respectively.

FIG. 3C shows one-dimensional dopant distributions in devices shown in FIGS. 3A and 3B along the cut lines.

FIG. 4 shows current-voltage curves for a device manufactured using a conventional method and for a device manufactured using a method according to an exemplary embodiment.

### DESCRIPTION OF THE EMBODIMENTS

Embodiments consistent with the disclosure include a method for suppressing dopant diffusion during a semiconductor device manufacturing process.

Hereinafter, embodiments consistent with the disclosure will be described with reference to the drawings. Wherever possible, the same reference numbers will be used throughout the drawings to refer to the same or like parts.

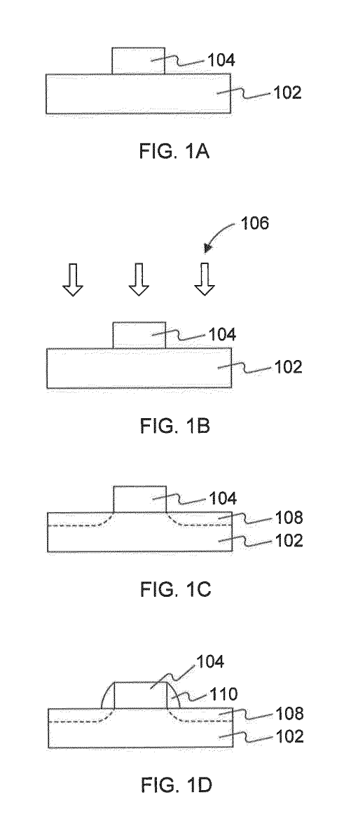

FIGS. 1A-1G schematically show an exemplary process for manufacturing a MOS transistor consistent with embodiments of the disclosure. In the description herein of the exemplary process shown in FIGS. 1A-1G, a p-MOS transistor is discussed as an example. It is noted that similar processes may be applied to other semiconductor devices, such as n-type MOS transistors.

As shown in FIG. 1A, a gate structure 104 is formed on a substrate 102. The substrate 102 may be, for example, an n-type silicon substrate. Depending on the type of transistor being manufactured, the gate structure 104 may include different layers, such as a gate insulating layer and a control gate electrode, or may include additional layers such as, for example, a tunneling layer or a floating gate electrode.

As shown in FIG. 1B, a lightly-doped drain (LDD) implantation is performed by implanting dopant ions 106 into the substrate 102, using the gate structure 104 as a mask. Since the gate structure 104 blocks part of the dopant ions 106, LDD regions 108 are formed in the substrate 102 at the sides of the gate structure 104, as shown in FIG. 1C.

The LDD implantation shown in FIG. 1B may include implanting p-type dopant ions into the substrate 102. In some embodiments, the dopant ions 106 include Group-III ions, e.g., boron (B) ions. The B ions may be implanted at a dose of about 1E13cm⁻² to about 1E14 cm⁻² and an implantation energy of about 10 KeV to about 30 KeV.

Referring to FIG. 1D, gate spacers 110 are formed on sidewalls of the gate structure 104. The gate spacers 110 include an insulating material, such as silicon nitride. The gate spacers 110 are formed by, for example, depositing an insulating layer over the entire surface of the substrate 102 followed by an etch back.

Referring to FIG. 1E, a pre-amorphization implantation (PAI) is performed by implanting ions 112 into the substrate 102 using the structure including the gate structure 104 and the gate spacers 110 as a mask. As understood by one skilled in the art, “pre-amorphization implantation” refers to an implantation performed before an impurity doping step, such as a heavy doping step for forming source/drain regions of a field-effect transistor, during a process for fabricating a semiconductor device, where such implantation “amorphizes” a portion of the semiconductor device on which the pre-amophization implantation is performed. As shown in FIG. 1 F, the PAI amorphizes a portion of the substrate 102, creating amorphous regions 113 at the sides of the structure including the gate structure 104 and the gate spacers 110.

The PAI helps to reduce a dopant channeling effect, which refers to an effect in which doping impurities (impurities doped in the subsequent doping step after the PAI, such as boron (B), described later) channel through spaces in a crystal lattice structure of a substrate and reach a depth greater than desired. The PAl reduces the dopant channeling effect by amorphizing the substrate 102, and thus reducing the spaces in the crystal lattice structure of the substrate 102, through which subsequently doped impurities may channel. As a consequence, a doping depth of the subsequently doped impurities is reduced and a doping profile thereof can be better controlled. Further, by performing the PAl before an impurity doping step, the number of excessive point defects and excessive interstitials, i.e., end-of-range (EOR) defects, can be reduced. Therefore, the subsequently doped impurities are less likely to form dopant-interstitial pairings and dopant-interstitial clusters, such as boron-interstitial pairs and boron-interstitial clusters when B is the dopant in the subsequent doping step. Consequently, transient enhanced diffusion of the subsequently doped impurities is suppressed and more dopant impurities can be activated. Thus, dopant activation is improved, and a lower sheet resistance R_{S} can be achieved.

Consistent with embodiments of the disclosure, conditions for the PAI can be controlled to control a depth of the amorphous regions 113 (also referred to as an amorphization depth, i.e., a distance from a surface of the substrate 102 to a bottom of the amorphous regions 113). In general, a larger amorphization depth results in fewer excessive point defects, fewer excessive interstitials, i.e., EOR defects, more dopant impurities being activated, and reduced TED. In some embodiments, the amorphization depth is controlled to be about 300 Å to about 1000 Å, which is larger than a depth of a highly-doped region described below.

Consistent with embodiments of the disclosure, the ions 112 may be ions from the same group in the periodic table as the element of which the substrate 102 is primarily composed. In some embodiments, the substrate 102 includes a silicon substrate, and thus the ions 112 can be Group-IV ions, such as carbon (C) or germanium (Ge). For example, C ions may be implanted at a dose of about 1E15cm⁻² to about 5E15 cm⁻² and an implantation energy of about 10 KeV to about 50 KeV. Alternatively, Ge ions may be implanted at a dose of about 1E15 cm⁻² to about 5E15 m⁻² and an implantation energy of about 10 KeV to about 50 KeV.

The PAI can be performed at a room temperature, i.e., about 21° C., or at a temperature lower than the room temperature. For example, the PAI can be performed at a low temperature of about 0° C. to about −100° C. An implantation at a low temperature is also referred to as a cryogenic implantation. The low temperature helps to reduce a dynamic annealing effect and lower a threshold dose needed to amorphize the crystal lattice of a substrate. As a consequence, with other conditions being the same, an implantation at a lower temperature may result in a larger amorphous depth.

After the PAI is performed, as shown in FIG. 1G, a high-doping implantation is performed by implanting dopant ions 114 into the substrate 102, using the structure including the gate structure 104 and the gate spacers 110 as a mask. As a result of the high-doping implantation, highly-doped regions 116 are formed in the substrate 102 at both sides of the gate structure 104, as shown in FIG. 1H. The highly-doped regions 116 at least partially overlap the LDD regions 108, and the highly-doped regions 116 and the LDD regions 108 together form the source/drain regions of the transistor being manufactured.

The high-doping implantation shown in FIG. 1G can include implanting p-type dopant ions into the substrate 102. In some embodiments, the dopant ions 106 include ions of Group-Ill elements, e.g., B ions or indium (In) ions, or ion clusters of Group-III elements and other elements, e.g., BF₂ ion clusters. The B ions can be implanted at a dose of about 5E14 cm⁻² to about 5E15 cm⁻² and an implantation energy of about 10 KeV to about 50 KeV.

In some embodiments, after the high-doping implantation, an annealing is performed, for example, to fix defects in the substrate 102 created by the implantation processes discussed above, and to activate the implanted dopant ions, such as the B ions. The annealing process can be performed at a temperature of about 900° C. to about 1200° C.

It is noted that in FIGS. 1B, 1E, and 1G, the implantations are represented by arrows pointing downward. This is for illustrative purpose and is not intended to indicate the actual implantation directions. That is, the directions at which ions are implanted towards the substrate 102 (also referred to as “implantation directions”) are not necessarily perpendicular to the surface of the substrate 102. For example, an implantation direction may be tilted by, e.g., about 7°, i.e., an angle between the implantation direction and a normal direction to the surface of the substrate 102 may be about 7°.

As a result of the above-described process, a semiconductor device is formed, such as the semiconductor device shown in FIG. 1H. The semiconductor device formed consistent with embodiments of the disclosure includes a substrate 102 such as a Si substrate, a gate structure 104, gate spacers 110 formed on both sides of the gate structure 104, and source/drain regions each including a LDD region 108 and a heavily-doped region 116. The source/drain regions contain dopant ions introduced by the PAI, which include, for example, C or Ge.

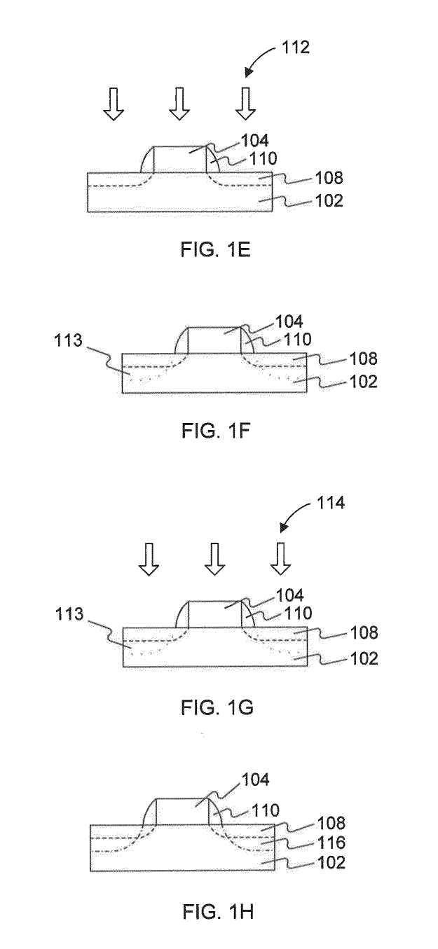

FIG. 2 illustrates an example of the effect of PAI on the diffusion of dopant ions. The diffusion profiles in FIG. 2 are obtained before an annealing is performed. In the example shown in FIG. 2, the dashed curve represents the diffusion of B when B ions are implanted using a conventional method, i.e., a process without PAl (hereinafter referred to as a “conventional implantation”). The solid curve represents the diffusion of B when B ions are implanted using a method consistent with embodiments of the disclosure, i.e., a process including PAI, such as PAl using Cat a low temperature (hereinafter referred to as a “cryogenic C-implantation”) before the high-doping B implantation. It is seen from FIG, 2 that, the diffusion of B is suppressed when a cryogenic C-implantation has been performed.

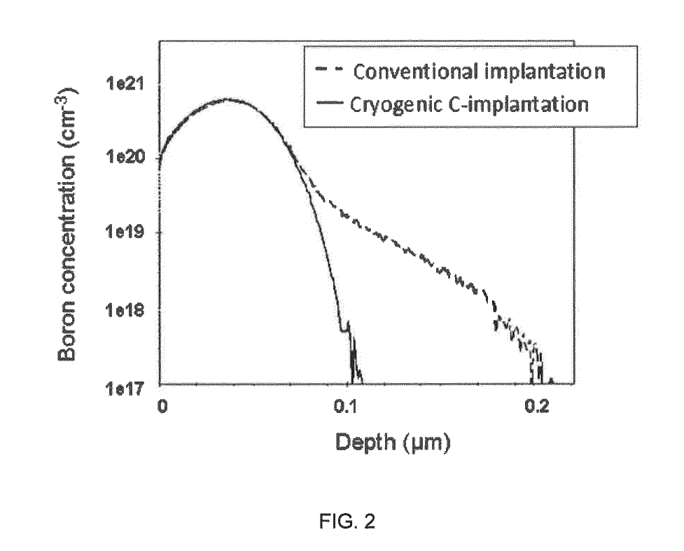

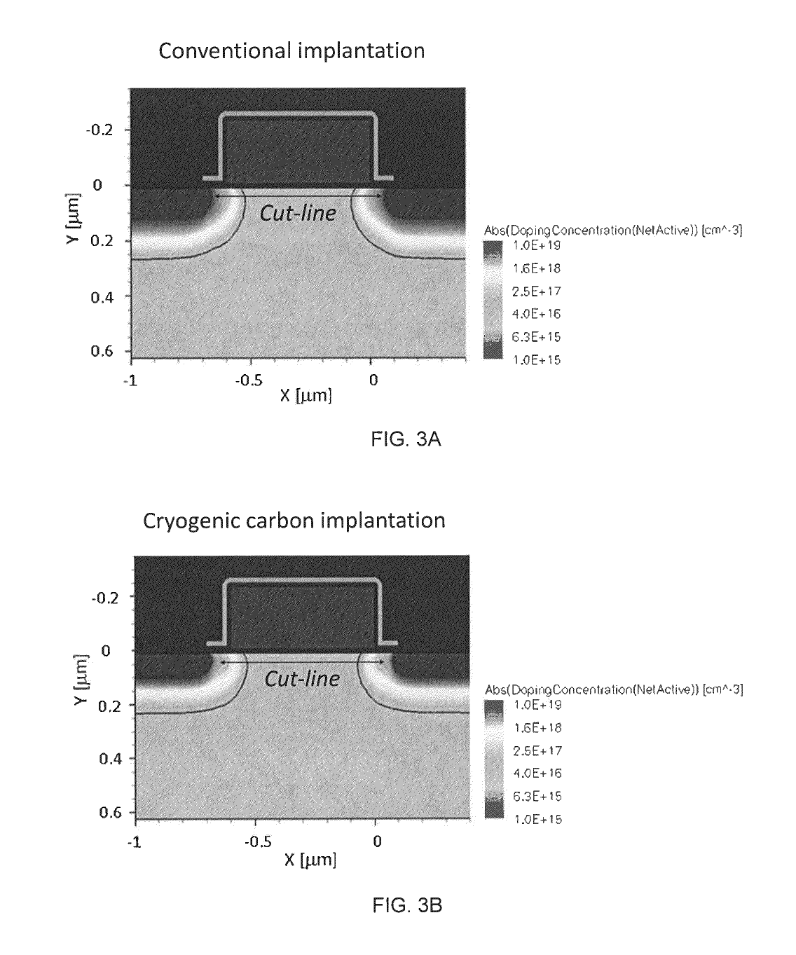

FIGS. 3A-3C show the comparison between a net-doping distribution in a device according to a conventional method and a net-doping distribution in a device according to a method consistent with embodiments of the disclosure, assuming all other conditions are the same. Specifically, FIGS. 3A-3C are simulation results, in which FIG. 3A shows the net-doping distribution with a conventional implantation, FIG. 3B shows the net-doping distribution with a cryogenic C-implantation, and FIG. 3C shows the net-doping along a cut line in each of the two devices shown in FIGS. 3A and 3B. In FIG. 3C, the dashed curve represents a doping profile corresponding to the conventional method, while the solid curve represents a doping profile corresponding to a method consistent with embodiments of the disclosure. It is seen from FIGS. 3A-3C that the diffusion of dopant ions is suppressed with cryogenic C-implantation and thus the highly-doped regions are better defined.

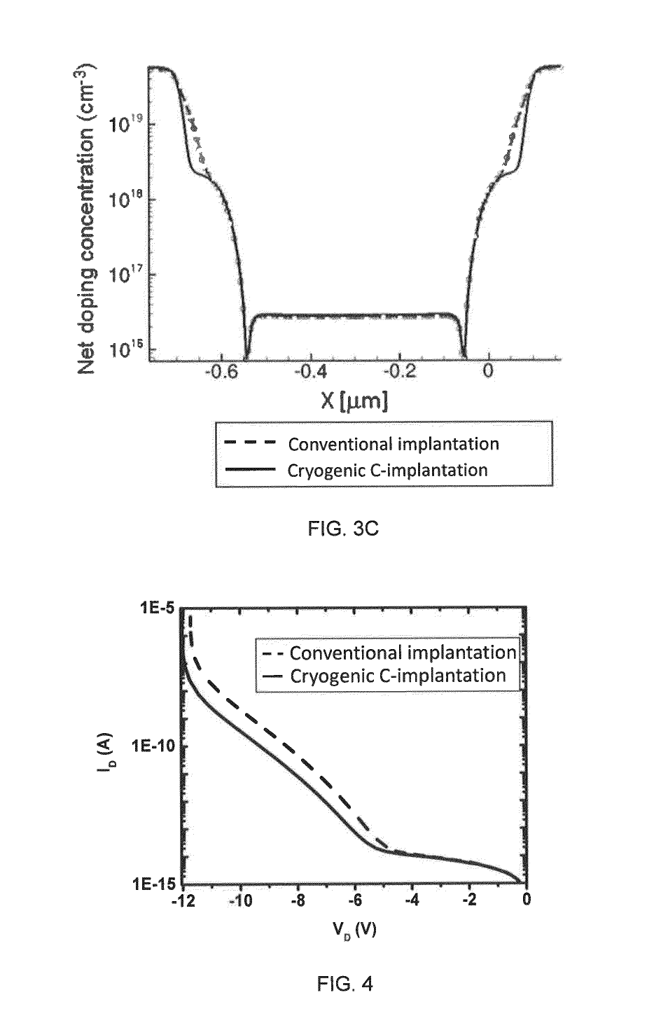

Due to the suppression of the dopant diffusion and thus better defined highly-doped regions, a device manufactured according to a method consistent with embodiments of the disclosure has a better breakdown performance, as compared to a device manufactured according to a conventional method. FIG. 4 shows I_{D}-V_{D} curves for a device manufactured with conventional implantation (the dashed curve) and a device manufactured with cryogenic C-implantation (the solid curve) measured when a voltage applied to the control gate electrode of the device, V_{G}, equals 0V. As used herein, V_{D} refers to a voltage applied to a drain of the device, and I_{D} refers to a current flowing through the drain of the device. Note that a voltage applied to a source of the device is 0V, i.e., the source is grounded. It is seen from FIG. 4 that the absolute value of the voltage V_{D} at which the current I_{D} in the device manufactured with cryogenic C-implantation sharply increases is larger than the absolute value of the voltage V_{D} at which the current I_{D} in the device manufactured with conventional implantation sharply increases. That is, the device manufactured with cryogenic C-implantation has a larger breakdown voltage than the device manufactured with conventional implantation.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

1. A method for forming a semiconductor device, comprising:
forming a gate structure over a substrate;
performing a lightly-doped drain (LDD) implantation of first dopant ions into the substrate using the gate structure as a mask to form LDD regions in the substrate;
performing, after the LDD implantation, a pre-amorphization implantation (PAI) into the substrate using the gate structure as a mask to pre-amorphize at least a portion of the LDD regions to form amorphous regions; and
performing, after the PAI, a high-doping implantation of second dopant ions into the substrate using the gate structure as a mask to form highly-doped regions at least partially overlapping the LDD regions,
wherein a depth of the amorphous regions is larger than a depth of the highly-doped regions.

2. The method of claim 1, wherein forming the gate structure over the substrate includes forming the gate structure over an n-type silicon substrate.

3. The method of claim 1, wherein performing the PAI includes implanting Ge ions into the substrate.

4. The method of claim 3, wherein implanting Ge ions into the substrate includes implanting Ge ions at a dose of about 1E15 cm⁻² to about 5E15 cm⁻².

5. The method of claim 3, wherein implanting Ge ions into the substrate includes implanting Ge ions at an implantation energy of about 10 KeV to about 50 KeV.

6. The method of claim 1, wherein performing the PAI includes implanting C ions into the substrate.

7. The method of claim 6, wherein implanting C ions into the substrate includes implanting C ions at a dose of about 1E15 cm⁻² to about 5E15 cm⁻².

8. The method of claim 6, wherein implanting C ions into the substrate includes implanting C ions at an implantation energy of about 10 KeV to about 50 KeV.

9. The method of claim 6, wherein implanting C ions into the substrate includes implanting C ions at an environmental temperature of about a room temperature to about −100° C.

10. The method of claim 9, where in implanting C ions into the substrate includes implanting C ions at an environmental temperature of about 0° C. to about −100° C.

11. The method of claim 1, wherein performing the LDD implantation includes implanting the first dopant ions as B ions into the substrate at a dose of about 1E13 cm⁻² to about 1E14 cm⁻².

12. The method of claim 1, wherein performing the LDD implantation includes implanting the first dopant ions as B ions into the substrate at an implantation energy of about 10 KeV to about 30 KeV.

13. The method of claim 1, wherein performing the high-doping implantation includes implanting the second dopant ions as B ions into the substrate at a dose of about 5E14 cm⁻² to about 5E15 cm⁻².

14. The method of claim 1, wherein performing the high-doping implantation includes implanting the second dopant ions as B ions into the substrate at an implantation energy of about 10 KeV to about 50 KeV.

15. The method of claim 1, wherein forming the gate structure comprises:
forming a gate insulating layer over the substrate; and
forming a gate electrode over the gate insulating layer.

16. The method of claim 1, further comprising:
forming, after the LDD implantation, gate spacers on sidewalls of the gate structure.

17. The method of claim 16, wherein:
performing the PAI includes performing the PAI using a structure including the gate structure and the gate spacers as a mask, and
performing the high-doping implantation includes performing the high-doping implantation using the structure including the gate structure and the gate spacers as a mask.

18. The method of claim 1, further comprising:
performing, after the high-doping implantation, an annealing.

19. A semiconductor device comprising:
a substrate including a first element;
a gate structure formed over the silicon substrate;
a source region and a drain region formed in the silicon substrate at sides of the gate structure, the source and drain regions containing a dopant including a second element different from the first element, and the first and second elements being from a same group of the periodic table.

20. The semiconductor device of claim 19, wherein:
the first element is silicon, and
the second element is one of carbon or germanium.
